(19) United States
(12) Patent Application Publication
(10) Pub. No.: US 2022/0375751 A1
(43) Pub. Date: Nov. 24, 2022

(54) INTEGRATED EPITAXY AND PRECLEAN SYSTEM

(71) Applicant: Applied Materials, Inc., Santa Clara, CA (US)

(72) Inventors: Yi-Chiau HUANG, Fremont, CA (US); Songjae Lee, San Jose, CA (US); Manoj Vellaikal, Sunnyvale, CA (US); Chen-Ying Wu, Santa Clara, CA (US); Eric Davey, Mountain View, CA (US); Saurabh Chopra, Santa Clara, CA (US)

(21) Appl. No.: 17/463,966

(22) Filed: Sep. 1, 2021

Related U.S. Application Data
(60) Provisional application No. 63/192,325, filed on May 24, 2021.

(51) Int. Cl. H01L 21/02; C30B 25/18; C23C 16/02; C23C 16/54

(52) U.S. Cl. CPC H01L 21/02661; H01L 21/02049; H01L 21/02381; H01L 21/02532; H01L 21/0262; C30B 25/186; C23C 16/0236; C23C 16/54

(57) ABSTRACT

Embodiments of the present disclosure generally relate to an integrated substrate processing system for cleaning a substrate surface and subsequently performing an epitaxial deposition process thereon. A processing system includes a film formation chamber, a transfer chamber coupled to the film formation chamber, and an oxide removal chamber coupled to the transfer chamber, the oxide removal chamber having a substrate support. The processing system includes a controller configured to introduce a process gas mixture into the oxide removal chamber, the process gas mixture including a fluorine-containing gas and a vapor including at least one of water, an alcohol, an organic acid, or combinations thereof. The controller is configured to expose a substrate positioned on the substrate support to the process gas mixture, thereby removing an oxide film from the substrate.

### CROSS-REFERENCE TO RELATED APPLICATIONS

This application claims the benefit of U.S. Provisional Patent Application Ser. No. 63/192,325, filed on May 24, 2021, the entirety of which is herein incorporated by reference.

### FIELD

Embodiments of the present disclosure generally relate to an apparatus and a method for cleaning a surface of a substrate. More particularly, embodiments disclosed herein relate to an integrated substrate processing system for cleaning a substrate surface and subsequently performing an epitaxial deposition process thereon.

### BACKGROUND

Integrated circuits are formed in and on silicon and other semiconductor substrates. In the case of single crystal silicon, substrates are made by growing an ingot from a bath of molten silicon, and then sawing the solidified ingot into multiple substrates. An epitaxial silicon layer may then be formed on the monocrystalline silicon substrate to form a defect free silicon layer that may be doped or undoped. Semiconductor devices, such as transistors, may be manufactured from the epitaxial silicon layer. The electrical properties of the formed epitaxial silicon layer are generally better than the properties of the monocrystalline silicon substrate.

Surfaces of the monocrystalline silicon and the epitaxial silicon layer are susceptible to contamination when exposed to typical substrate fabrication facility ambient conditions. For example, a native oxide layer may form on the monocrystalline silicon surface prior to deposition of the epitaxial layer due to handling of the substrates and/or exposure to ambient environment in the substrate processing facility. Additionally, foreign contaminants such as carbon and oxygen species present in the ambient environment may deposit on the monocrystalline surface. The presence of a native oxide layer or contaminants on the monocrystalline silicon surface negatively affects the quality of an epitaxial layer subsequently formed on the monocrystalline surface. Conventional preclean processes are often carried out in one or more stand-alone vacuum process chambers, which may increase substrate handling time and chances of exposing substrates to ambient environment.

Therefore, there is a need in the art to provide an improved substrate processing system for cleaning a substrate surface prior to performing an epitaxial deposition process that minimizes substrate handling time and exposure to ambient environment.

### SUMMARY

This disclosure describes a processing system, including a film formation chamber, a transfer chamber coupled to the film formation chamber, and an oxide removal chamber coupled to the transfer chamber, the oxide removal chamber having a substrate support. The processing system includes a controller configured to introduce a process gas mixture into the oxide removal chamber, the process gas mixture including a fluorine-containing gas and a vapor including at least one of water, an alcohol, an organic acid, or combinations thereof. The controller is configured to expose a substrate positioned on the substrate support to the process gas mixture, thereby removing an oxide film from the substrate.

Also described herein is a method of processing a substrate, including removing oxide from a substrate disposed in a first process chamber by exposing the substrate to a process gas mixture including a fluorine-containing gas and a vapor including at least one of water, an alcohol, an organic acid, or combinations thereof. The method includes transferring the substrate from the first process chamber to a second process chamber under vacuum or inert environment and forming a film on the substrate disposed in the second process chamber.

Also described herein is a processing system, including a film formation chamber, a first transfer chamber coupled to the film formation chamber, a pass-through station coupled to the first transfer chamber, a second transfer chamber coupled to the pass-through station, a first oxide removal chamber coupled to the second transfer chamber, and a load lock chamber coupled to the first oxide removal chamber. The first oxide removal chamber, the second transfer chamber, the pass-through station, the first transfer chamber, and the film formation chamber are maintained under vacuum or inert environment. The first oxide removal chamber includes a first substrate support. The system includes a computer readable medium storing instructions, that, when executed by a processor of the processing system, cause the system to remove oxide from a first substrate disposed in the first oxide removal chamber by exposing the first substrate to a process gas mixture including a fluorine-containing gas and a vapor including at least one of water, an alcohol, an organic acid, or combinations thereof.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a processing method, according to certain embodiments.

FIG. 2 is a cross-sectional view of a processing chamber used to perform at least some of the cleaning processes of FIG. 1, according to certain embodiments.

FIG. 3 illustrates a schematic sectional view of a process chamber for performing an epitaxial deposition process, according to certain embodiments.

FIG. 4 illustrates an exemplary integrated vacuum processing system for performing cleaning and deposition processes as described herein.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments disclosed herein relate to an integrated substrate processing system for cleaning a substrate surface and subsequently performing an epitaxial deposition process thereon.

Certain embodiments disclosed herein provide surface oxide removal through exposure of the substrate to a mixture of fluorine-containing gas and a vapor including water, alcohol, and/or organic acid. Vapor phase mixtures disclosed herein avoid the formation of solid byproducts which are characteristic of reactions with conventional process gas mixtures which include ammonia (NH₃). For example, the presence of NH₃ in a fluorine-containing process gas leads to the formation of solid ammonium salts (e.g., (NH₄)₂SiF₆, or ammonium fluorosilicate). Ammonium fluorosilicate forms solid crystals which are deposited within features formed on the substrate surface. Integrated systems are designed in which the substrate is maintained under vacuum or inert environment in order to reduce or prevent growth of native oxides, such as silicon oxide (e.g., SiO₂) on the substrate surface. However, the formation of solid crystals from conventional process gases negates much of the efficiency gain which would otherwise result from use of such systems. Beneficially, certain embodiments disclosed herein provide surface oxide removal without the formation of solid byproducts such as salts.

Removal of solid byproducts from within features formed on the substrate surface may require thermal treatment (e.g., heating to decompose salt crystals) which increases processing time and processing complexity. For smaller feature sizes (e.g., having a critical dimension of about 25 nm or less, such as about 10 nm to about 25 nm, or having an aspect ratio (i.e., ratio of depth to width) of about 25 or less, such as about 10 to about 25), removal of solid byproducts presents an even greater challenge which may not be addressed using conventional techniques. Process gas mixtures disclosed herein are able to avoid the formation of solid byproducts altogether which circumvents the need for thermal treatment and improves cleaning efficiency and throughput.

Certain process gas mixtures and process parameters disclosed herein improve etching selectivity for enhanced removal of native oxide compared to other materials, such as low-k dielectric materials, silicon, silicon germanium, and silicon nitride (e.g., SiN), among others, when compared to conventional fluorine- and ammonia-containing process gases with or without plasma formation.

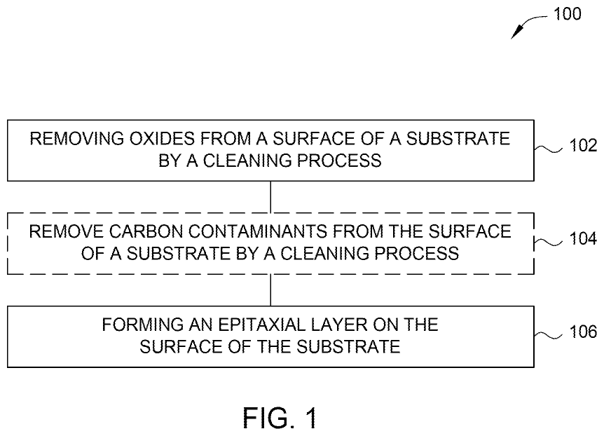

FIG. 1 illustrates a processing method 100, according to certain embodiments. At activity 102, oxides are removed from a surface of a semiconductor substrate using a cleaning process. Oxide removal at activity 102 may also be referred to as “precleaning” or “etching.” The substrate may include a silicon-containing material and the surface may include a material, such as silicon (Si), germanium (Ge) or silicon germanium alloys (SiGe). In some examples, the Si, Ge, or SiGe surface may have an oxide layer, such as a native oxide layer, and contaminants disposed thereon. Due to the sensitivity of epitaxial deposition processes to oxides and contaminants, such as carbon-containing contaminants, surface contamination resulting from exposure to cleanroom environments for a few hours can become significant enough for the accumulated oxides and contaminants to affect the quality of a subsequently formed epitaxial layer.

The substrate surface may be cleaned by performing an oxide removal process and a contaminant removal process. In one example, the oxides are removed from the surface of the substrate using a cleaning process (activity 102), and the contaminants, such as carbon-containing contaminants, are removed from the surface of the substrate using a reducing process. The cleaning process may include a vapor. In some examples, the cleaning process may be performed without the formation of plasma and/or without exposing the substrate to radicals or radical species. In some examples, the process gas may be free of ammonia. The process gas may include a fluorine-containing gas mixed with a vapor. In some examples, the process gas may further include one or more purge gases or carrier gases (e.g., hydrogen, helium, and/or argon).

In some examples, the fluorine-containing gas may include hydrogen fluoride (e.g., HF), anhydrous hydrogen fluoride, fluorine (F₂), nitrogen fluoride (e.g., nitrogen trifluoride (NF₃)), carbon fluoride (e.g., carbon tetrafluoride (CF₄), hexafluoroethane (C₂F₆), trifluoromethane (CHF₃), difluoromethane (CH₂F₂), octofluoropropane (C₃F₈), octofluorocyclobutane (C₄F₈), octofluoro[1-]butane (C₄F₈), octofluoro[2-]butane (C₄F₈), or octofluoroisobutylene (C₄F₈)), sulfur fluoride (e.g., sulfur hexafluoride (SF₆)), or combinations thereof. In some examples, a flow rate of the fluorine-containing gas may be about 50 sccm to about 500 sccm for a 300 mm substrate. In some examples, a concentration of the fluorine-containing gas within the processing chamber (e.g., in contact with the substrate surface) may be about 5% wt/wt to about 75% wt/wt of the total process gas mixture including any other components (e.g., carrier or purge gases).

In some examples the vapor may include water (e.g., distilled water), a primary alcohol (e.g., methyl alcohol, ethyl alcohol, propyl alcohol, butyl alcohol, or isobutyl alcohol), a secondary alcohol (e.g., isopropyl alcohol or sec-butyl alcohol), a tertiary alcohol (e.g., tert-butyl alcohol), a cyclic alcohol (e.g., cyclohexyl alcohol), a complex alcohol (e.g., 4-ethyl-3-hexanol), a C1 alcohol, a C2 alcohol, a C3 alcohol, a C1-C2 alcohol, a C1-C3 alcohol, a C1-C4 alcohol, an organic acid, or combinations thereof. In some examples, the vapor may increase a rate of reaction between the fluorine-containing gas and surface oxides. In some examples, lower carbon number alcohols may increase the reaction rate to a greater degree compared to higher carbon number alcohols (e.g., a relative rate of reaction may be C1 alcohol>C2 alcohol>C3 alcohol). In some examples, a flow rate of the vapor may be about 5 sccm to about 500 sccm for a 300 mm substrate. In some examples, a flow ratio of the fluorine-containing gas to the vapor may be about 10:1 to about 1:10. In some examples, a concentration of the vapor may be about 5 wt/wt to about 75 wt/wt of the total process gas mixture including any other components (e.g., carrier or purge gases).

In operation, the fluorine-containing gas may be mixed with the vapor for charging to the process chamber. In some other examples, the gases may be provided to the process chamber through different pathways (i.e., separately) and mixed after arrival to the process chamber and before contacting the substrate. Mixing of the gases may be spatially separated from a processing region in which the substrate is disposed. The term “spatially separated” described herein may refer to a mixing region that is separated from a substrate processing region by one or more chamber components, or even a conduit between a mixing chamber and a substrate processing chamber. In some examples, a processing temperature, which may refer to a temperature of the mixed process gas within the processing chamber (e.g., a temperature of the mixed process gas in contact with the substrate surface), may be about 0° C. or less, such as about −50° C. to about 40° C. In some examples a pressure in the processing chamber may be within a range of about 0.5 Torr to about 20 Torr.

The preclean process is largely conformal and selective for oxide layers, and thus does not readily etch silicon (e.g., low-k spacers or other dielectric materials), germanium, or nitride layers regardless of whether the layers are amorphous, crystalline or polycrystalline. Selectivity of the process gas for oxide compared to silicon or germanium is at least about 3:1, such as about 5:1 or greater, such as about 10:1 or greater. The process gas is also highly selective of oxide compared to nitride. The selectivity of the process gas compared to nitride is at least about 3:1, such as about 5:1 or greater, such as about 10:1 or greater.

In some embodiments, either during the preclean process or after performing the preclean process, thermal energy may be applied to the processed substrate to help remove any generated byproducts. In some embodiments, the thermal energy is provided via a radiant, convective and/or conductive heat transfer process that causes the unwanted byproducts found on the substrate surface to sublimate.

At optional activity 104, a second cleaning process may be performed by removing carbon contaminants from the surface of the substrate. Although activity 104 is shown after activity 102, in some other examples, activity 104 may be before activity 102. The cleaning process may include a plasma process performed in a plasma-cleaning chamber. The plasma process may use a plasma formed from a gas including hydrogen (H₂), helium (He), ammonia (NH₃), a fluorine-containing gas, or a combination thereof. The plasma may be inductively or capacitively coupled, the plasma may be formed by a microwave source in a processing chamber, or the plasma may be formed by a remote plasma source.

At activity 106, an epitaxial layer is formed on the surface of the substrate. If cleaned prior, as described above, the surface of the substrate is uniformly oxide and contaminant free which improves the quality of layers subsequently formed on the surface of the substrate. An exemplary epitaxial process may be a selective epitaxial process performed at a temperature that is less than about 800° C., for example about 450° C. to about 650° C. The epitaxial layer may be formed using a high temperature chemical vapor deposition (CVD) process. The epitaxial layer may be a crystalline silicon, germanium, or silicon germanium, or any suitable semiconductor material such as a Group III-V compound or a Group II-VI compound. In one exemplary thermal CVD process, processing gases such as chlorosilanes SiHₓCl₄₋ₓ (mono, di, tri, tetra), silanes SiₓH_{2X+2} (silane, disilane, trisilane, etc.), germanes GeₓH₂ₓ₊₂ (germane, digermane, etc.), hydrogen chloride HCl, chlorine gas (Cl₂), or combinations thereof are used to form the epitaxial layer. The processing temperature is under 800° C., such as about 300° C. to about 600° C., for example about 450° C., and the processing pressure is within a range of about 5 Torr to about 600 Torr. An exemplary processing chamber that can be used to perform the epitaxial deposition process is the Centura™ Epi chamber, which is available from Applied Materials, Inc., of Santa Clara, Calif. Chambers from other manufacturers may also be used.

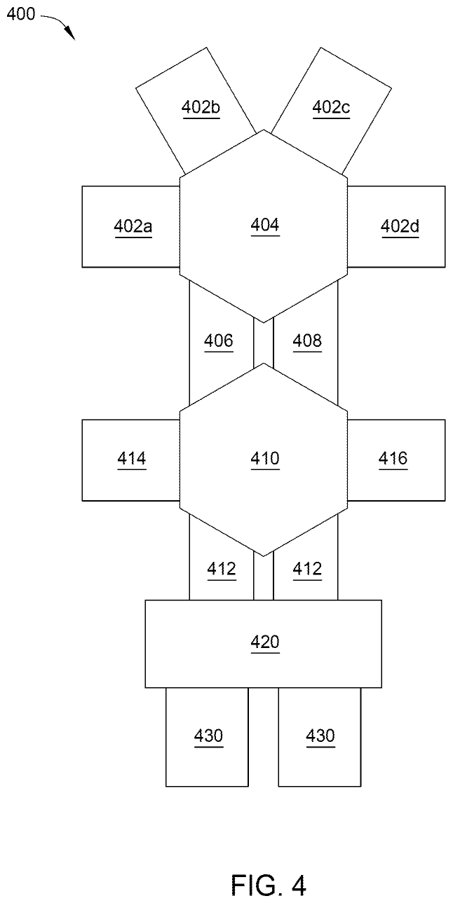

Activities 102, 104 and 106 may be performed in one processing system, such as the processing system illustrated in FIG. 4, and further described below. An optional thermal treatment may also be performed between or after the processes 102 and 104, before performing the layer formation process of 106, to remove any residual byproducts or contaminants, and to anneal the surface to remove any surface defects. Such an anneal may be performed under a hydrogen atmosphere, optionally including an inert gas such as argon or helium, and may be performed at temperatures of about 400° C. to about 800° C. and pressures from about 1 Torr to about 300 Torr.

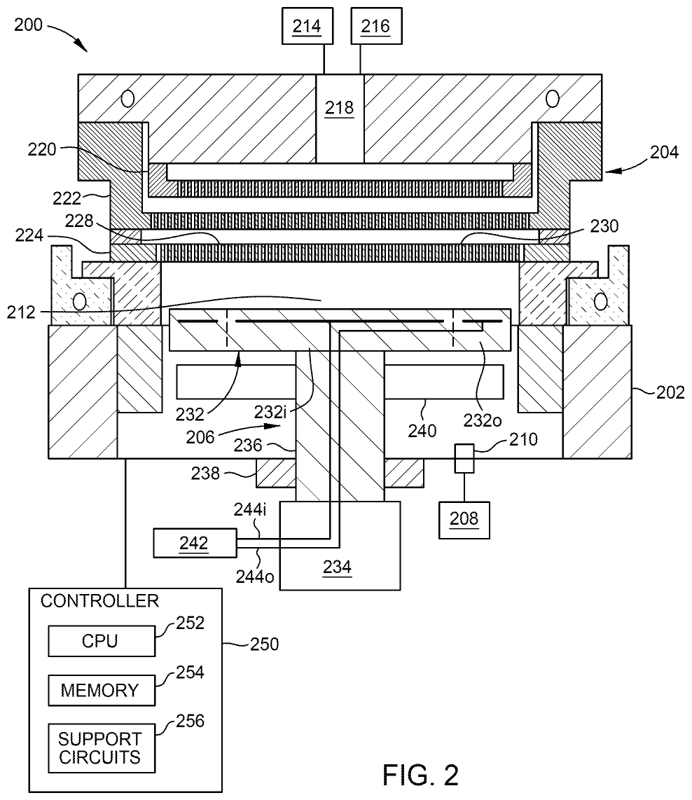

FIG. 2 is a cross sectional view of a processing chamber 200 that is adapted to perform at least some of the cleaning processes of activity 102, and thus is configured to remove contaminants, such as oxides, from a surface of a substrate.

The processing chamber 200 may be particularly useful for performing a vapor phase cleaning process. The processing chamber 200 generally includes a chamber body 202, a lid assembly 204, and a support assembly 206. The lid assembly 204 is disposed at an upper end of the chamber body 202, and the support assembly 206 is at least partially disposed within the chamber body 202. A vacuum system can be used to remove gases from processing chamber 200. The vacuum system includes a vacuum pump 208 coupled to a vacuum port 210 disposed in the chamber body 202.

The lid assembly 204 includes a plurality of stacked components configured to provide gases to a processing region 212 within the chamber 200. The lid assembly 204 is connected to a first gas source 214 and a second gas source 216. Gases from the first gas source 214 and second gas source 216 are introduced to the lid assembly 204 through a gas port 218. In some examples, the first gas source 214 may provide at least a first part of a process gas (e.g. a fluorine-containing component of the process gas described above with respect to activity 102 of FIG. 1). In some examples, the second gas source 216 may provide a second part of the process gas (e.g., a vapor component of the process gas described above with respect to activity 102 of FIG. 1). In some examples, one or more purge gases or carrier gases may also be delivered to the processing region 212 from the first gas source 214, second gas source 216, or from another gas source.

The lid assembly 204 generally includes a first plate 220, a second plate 222 below the first plate 220, and a showerhead 224 below the second plate 222 and above the processing region 212. Each of the first plate 220, second plate 222, and showerhead 224 includes multiple apertures formed therethrough and connecting gas regions above and below each respective piece. Therefore, the gases introduced to the lid assembly 204 through the gas port 218 flow through each piece of the lid assembly 204 in that order. In the example illustrated in FIG. 2, the showerhead 224 is a dual channel showerhead which has a first set of channels 228 and a second set of channels 230. The dual channel showerhead may be particularly advantageous to improve mixing of different gases coming from the first gas source 214 and second gas source 216.

The support assembly 206 (also referred to as a “pedestal”) includes a substrate support 232 to support a substrate thereon during processing. The substrate support 232 has a flat, or a substantially flat, substrate supporting surface. As shown, the substrate support 232 includes two independent temperature control zones (referred to as “dual zone”) to control substrate temperature for center-to-edge processing uniformity and tuning. In the example illustrated in FIG. 2, the substrate support 232 has an inner zone 232i and an outer zone 232o surrounding the inner zone 232i. In some other examples, the substrate support 232 may have more than two independent temperature control zones (referred to as “multi zone”).

The substrate support 232 is coupled to an actuator 234 by a stem 236 which extends through a centrally-located opening formed in a bottom of the chamber body 202. The actuator 234 is flexibly sealed to the chamber body 202 by bellows 238 that prevent vacuum leakage around the stem 236. The actuator 234 allows the substrate support 232 to be moved vertically within the chamber body 202 between a processing position and a loading position. The loading position is slightly below a substrate opening 240 formed in a sidewall of the chamber body 202.

The processing chamber 200 also includes an ultra-low temperature kit 242 for lowering a temperature of the substrate to be processed, which can improve selectivity for oxide removal (e.g., native oxide removal) compared to other materials, such as low-k dielectric materials and silicon nitride (e.g., SiN), among others. In some examples, the temperature of the substrate to be processed and/or a temperate of the substrate support 232 may be lowered to about −30° C. to about 10° C. The ultra-low temperature kit 242 provides a continuous flow of ultra-low temperature coolant to the substrate support 232 which cools the substrate support 232 to a desired temperature. In some examples, the ultra-low temperature coolant may include perfluorinated, inert polyether fluids (e.g., Galden® fluids). In the example illustrated in FIG. 2, the ultra-low temperature coolant is provided to the inner zone 232i and outer zone 232o of the substrate support 232 through inner coolant channel 244i and outer coolant channel 244o, respectively. The coolant channels are drawn schematically in FIG. 2 and may have a different arrangement from what is shown. For example, each coolant channel may be in the form of a loop.

A system controller 250, such as a programmable computer, is coupled to the processing chamber 200 for controlling the processing chamber 200 or components thereof. For example, the system controller 250 may control the operation of the processing chamber 200 using a direct control of the support assembly 206, vacuum pump 208, first gas source 214, second gas source 216, actuator 234, and/or ultra-low temperature kit 242 or using indirect control of other controllers associated therewith. In operation, the system controller 250 enables data collection and feedback from the respective components to coordinate processing in the processing chamber 200.

The system controller 250 includes a programmable central processing unit (CPU) 252, which is operable with a memory 254 (e.g., non-volatile memory) and support circuits 256. The support circuits 256 are conventionally coupled to the CPU 252 and comprise cache, clock circuits, input/output subsystems, power supplies, and the like, and combinations thereof coupled to the various components of the processing chamber 200.

In some embodiments, the CPU 252 is one of any form of general purpose computer processor used in an industrial setting, such as a programmable logic controller (PLC), for controlling various monitoring system component and sub-processors. The memory 254, coupled to the CPU 252, is non-transitory and is typically one or more of readily available memory such as random access memory (RAM), read only memory (ROM), floppy disk drive, hard disk, or any other form of digital storage, local or remote.

Herein, the memory 254 is in the form of a computer-readable storage media containing instructions (e.g., non-volatile memory), that when executed by the CPU 252, facilitates the operation of the processing chamber 200. The instructions in the memory 254 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

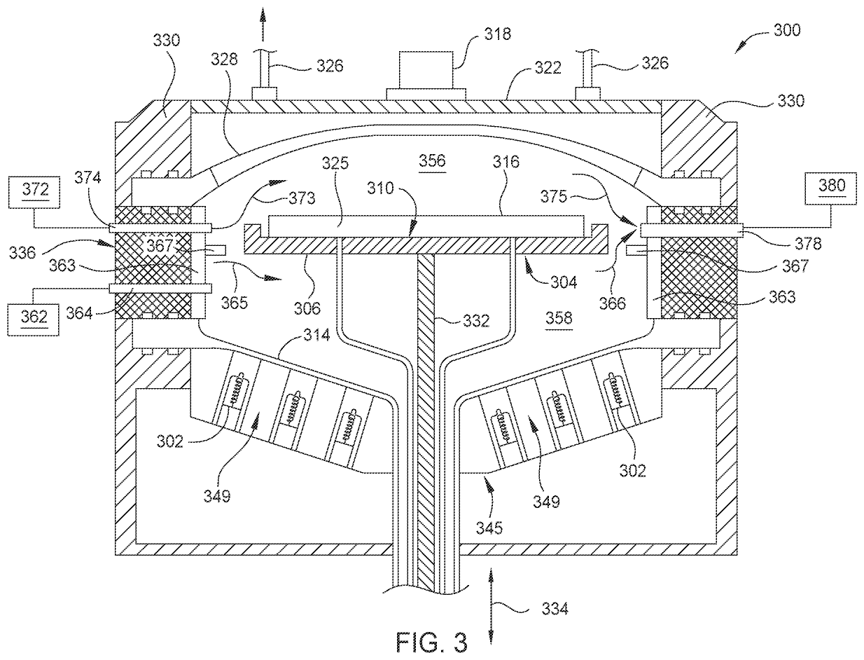

FIG. 3 illustrates a schematic sectional view of a process chamber 300 for performing an epitaxial deposition process, according to certain embodiments. The process chamber 300 may be used to process one or more substrates, including the deposition of a material on an upper surface of a substrate 325. The process chamber 300 includes an array of radiant heating lamps 302 for heating, among other components, a back side 304 of a substrate support 306 disposed within the process chamber 300. The substrate support 306 may be a disk-like substrate support 306 as shown, or may be a ring-like substrate support (having a central opening), which supports the substrate from the edge of the substrate to facilitate exposure of the substrate to the thermal radiation of the lamps 302.

The substrate support 306 is located within the process chamber 300 between an upper dome 328 and a lower dome 314. The upper dome 328, the lower dome 314 and a base ring 336 that is disposed between the upper dome 328 and lower dome 314 generally define an internal region of the process chamber 300. The substrate 325 (not to scale) is transferred into the process chamber 300 and positioned onto the substrate support 306 through a loading port.

The substrate support 306 is supported by a central stem 332, which moves the substrate 325 in a vertical direction 334 during loading and unloading, and in some instances, during processing of the substrate 325. The substrate support 306 is shown in an elevated processing position in FIG. 3 but may be vertically traversed by an actuator coupled to the central stem 332 to a loading position below the processing position. When lowered below the processing position, lift pins may contact the substrate 325 and raise the substrate 325 from the substrate support 306. A robot may then enter the process chamber 300 to engage and remove the substrate 325 therefrom though the loading port. The substrate support 306 then may be actuated vertically to the processing position to place the substrate 325, with a device side 316 facing up, on a front side 310 of the substrate support 306.

The substrate support 306, while located in the processing position, divides the internal volume of the process chamber 300 into a process gas region 356 that is above the substrate 325, and a purge gas region 358 below the substrate support 306. The substrate support 306 is rotated during processing by the central stem 332 to minimize the effect of thermal and process gas flow spatial anomalies within the process chamber 300 and thus facilitate uniform processing of the substrate 325. The substrate support 306 may be formed from silicon carbide or graphite coated with silicon carbide to absorb radiant energy from the lamps 302 and conduct the radiant energy to the substrate 325.

In general, the central window portion of the upper dome 328 and the bottom of the lower dome 314 are formed from an optically transparent material such as quartz. The thickness and the degree of curvature of the upper dome 328 may be configured to provide a flatter geometry for uniform flow uniformity in the process chamber.

The array of lamps 302 are disposed adjacent to and beneath the lower dome 314 in a predetermined manner around the central stem 332 to independently control the temperature at various regions of the substrate 325 as the process gas passes over, which facilitates the deposition of a material onto the upper surface of the substrate 325. While not discussed here in detail, in some examples, the deposited material may include gallium arsenide, gallium nitride, or aluminum gallium nitride. In some examples, an array of radiant heating lamps, such as the lamps 302, may be disposed over the upper dome 328.

The lamps 302 include bulbs configured to heat the substrate 325 to a temperature within a range of about 200 degrees C. to about 1600 degrees C. Each lamp 302 is coupled to a power distribution board through which power is supplied thereto. The lamps 302 are positioned within a lamphead 345 which may be cooled during or after processing by, for example, a cooling fluid introduced into channels 349 located between the lamps 302. The lamphead 345 conductively and radiatively cools the lower dome 314 due in part to the close proximity of the lamphead 345 to the lower dome 314. The lamphead 345 may also cool the lamp walls and reflector walls around the lamps. In some examples, the lower dome 314 may be cooled through convection. Depending upon the application, the lamphead 345 may or may not be in contact with the lower dome 314.

A circular shield 367 is disposed around the substrate support 306 and surrounded by a liner assembly 363. The shield 367 prevents or minimizes leakage of heat/light noise from the lamps 302 to the device side 316 of the substrate 325 while providing a pre-heat zone for the process gases. The shield 367 may be made from CVD SiC, sintered graphite coated with SiC, grown SiC, opaque quartz, coated quartz, or another similar, suitable material that is resistant to chemical breakdown by process and purging gases.

The liner assembly 363 is sized to be nested within or surrounded by an inner circumference of the base ring 336. The liner assembly 363 shields the processing volume (i.e., the process gas region 356 and purge gas region 358) from metal walls of the process chamber 300 which may react with precursors and cause contamination in the processing volume. While the liner assembly 363 is shown as a single body, the liner assembly 363 may include one or more liners with different configurations.

An optical pyrometer 318 may be used for temperature measurement and control. In the illustrated example, the optical pyrometer 318 is located above the upper dome 328 for measuring temperature on the device side 316 of the substrate 325. This positioning provides radiation-sensing of the substrate 325 which conducts heat from the substrate support 306, with minimal background radiation from the lamps 302 directly reaching the optical pyrometer 318. In some other examples, an optical pyrometer may be located below the back side 304 of the substrate support 306 for measuring temperature on the back side 304.

A reflector 322 is located outside the upper dome 328 to reflect light that is radiating off the substrate 325 back onto the substrate 325. The reflector 322 is secured to the upper dome 328 using a clamp ring 330. The reflector 322 may be formed of a metal such as aluminum or stainless steel. The efficiency of the reflection may be improved by coating a reflector area with a highly reflective coating such as gold. The reflector 322 has a pair of channels 326 connected to a cooling source. The channels 326 connect to a passage formed on a side of the reflector 322 for cooling the reflector 322. The passage may carry a flow of fluid such as water and may run horizontally along the side of the reflector 322 in any desired pattern covering a portion or entire surface of the reflector 322.

Process gas supplied from a process gas supply source 372 is introduced into the process gas region 356 through a process gas inlet 374 formed in a sidewall of the base ring 336. The process gas inlet 374 is configured to direct the process gas in a generally radially inward direction. During the film formation process, the substrate support 306 may be located in the processing position, which is adjacent to and at about the same elevation as the process gas inlet 374, allowing the process gas to flow up and around along flow path 373 across the upper surface of the substrate 325 in a laminar flow. The process gas exits the process gas region 356 (along flow path 375) through a gas outlet 378 located on the side of the process chamber 300 opposite the process gas inlet 374. Removal of the process gas through the gas outlet 378 may be facilitated by a vacuum pump 380 coupled to the gas outlet 378. The process gas inlet 374 and the gas outlet 378 are aligned with each other and disposed approximately at the same elevation (e.g., coplanar). Such alignment, when combined with a flatter upper dome 328 enables a generally planar, uniform gas flow across the substrate 325. Further radial uniformity may be provided by the rotation of the substrate 325 through the substrate support 306.

A purge gas may be supplied from a purge gas source 362 to the purge gas region 358 through a purge gas inlet 364 (or through the process gas inlet 374) formed in the sidewall of the base ring 336. The purge gas inlet 364 is disposed at an elevation below the process gas inlet 374. The circular shield 367 is disposed between the process gas inlet 374 and the purge gas inlet 364. In some examples, a pre-heat ring may be disposed between the process gas inlet 374 and the purge gas inlet 364. The purge gas inlet 364 is configured to direct the purge gas in a generally radially inward direction. During the film formation process, the substrate support 306 may be located at a position such that the purge gas flows down and around along flow path 365 across the back side 304 of the substrate support 306 in a laminar flow. The flow of the purge gas may prevent or substantially reduce the flow of the process gas from entering into the purge gas region 358, or to reduce diffusion of the process gas entering the purge gas region 358 (i.e., the region under the substrate support 306). The purge gas exits the purge gas region 358 (along flow path 366) and is exhausted out of the process chamber through the gas outlet 378, which is located on the side of the process chamber 300 opposite the purge gas inlet 364. In some examples, a controller (e.g., the controller 250 shown in FIG. 2 or another similar controller) may be coupled to the process chamber 300 for controlling the process chamber 300 or components thereof.

FIG. 4 illustrates an exemplary integrated vacuum processing system 400 that can be used to complete the processing sequence 100 illustrated in FIG. 1, according to certain embodiments. The vacuum processing system 400 has an internal volume which is isolated from ambient environment. As shown in FIG. 4, a plurality of processing chambers 402a, 402b, 402c, 402d are coupled to a first transfer chamber 404. The processing chambers 402a-402d may be used to perform any substrate related processes, such as annealing, chemical vapor deposition, physical vapor deposition, epitaxial process, etching process, thermal oxidation or thermal nitridation process, degassing etc. In one example, the processing chamber 402a may be a film formation chamber, such as a vapor phase epitaxy deposition chamber, for example an Epi chamber available from Applied Materials, Santa Clara, Calif., that is capable of forming a crystalline silicon or silicon germanium. In some examples, the processing chamber 402a may be an epitaxy deposition chamber such as the process chamber 300 described in FIG. 3.

The processing chamber 402b may be a rapid thermal processing chamber (RTP). The processing chamber 402c may be a plasma etching chamber or a plasma cleaning chamber. The processing chamber 402d may be a degassing chamber. The first transfer chamber 404 is also coupled to at least one transition station, for example a pair of pass-through stations 406, 408. The pass-through stations 406, 408 maintain vacuum or inert environment conditions while allowing substrates to be transferred between the first transfer chamber 404 and a second transfer chamber 410. The first transfer chamber 404 may have a robotic substrate handling mechanism for transferring substrates between the pass-through stations 406, 408 and any of the processing chambers 402a-402d. The processing chambers 402a-402d are shown configured in a certain order in FIG. 4, but the processing chambers 402a-402d may be configured in any desired order.

One end of the pass-through stations 406, 408 is coupled to the second transfer chamber 410. Therefore, the first transfer chamber 404 and the second transfer chamber 410 are separated and connected by the pass-through stations 406, 408. The second transfer chamber 410 is coupled to a first preclean chamber 414 and a second preclean chamber 416, each of which may be an oxide removal chamber such as the processing chamber 200 described in FIG. 2 that is adapted to perform at least some of the processes of activity 102 for removing oxides from a surface of a substrate. In one example, each of the first preclean chamber 414 and second preclean chamber 416 may be a Siconi™ or Selectra™ chamber, which are available from Applied Materials, Santa Clara, Calif.

In one example, the at least one transition station, for example one of the pass-through stations 406, 408, may be a plasma-cleaning chamber. Alternatively, a plasma-cleaning chamber may be coupled to one of the pass-through stations 406, 408 for removing contaminants from the surface of the substrate. Thus, the processing system 400 may have a plasma-cleaning chamber that is, or is connected to, one of the pass-through stations 406, 408. The plasma-cleaning chamber may be adapted to perform at least some of the processes of activity 102 for removing contaminants from the surface of the substrate. In one example, a plasma-cleaning chamber may be coupled to both of the pass-through stations 406 and 408.

The second transfer chamber 410 may also have a robotic substrate handling mechanism for transferring substrates between a set of load lock chambers 412 and the first preclean chamber 414 or the second preclean chamber 416. A factory interface 420 is connected to the second transfer chamber 410 by the load lock chambers 412. The factory interface 420 is coupled to one or more pods 430 on the opposite side of the load lock chambers 412. The pods 430 may be front opening unified pods (FOUP) that are accessible from a clean room.

While two transfer chambers are shown, it is contemplated that either of the transfer chambers may be omitted. In one example in which the second transfer chamber 410 is omitted, the first preclean chamber 414 and second preclean chamber 416 may be disposed within or coupled to the first transfer chamber 404 at the location currently shown as occupied by the pass-through stations 406 and 408. The first transfer chamber 404 may be coupled to one or more processing chambers capable of forming crystalline silicon or silicon germanium, such as an epitaxy chamber, for example a Centura™ Epi chamber available from Applied Materials, Inc., of Santa Clara, Calif. Alternatively, the first transfer chamber 404 may be omitted and the second transfer chamber 410 may be configured to be coupled to one or more processing chambers capable of forming crystalline silicon or silicon germanium.

In operation, substrates are removed, one at a time, from the pods 430 and transferred to the vacuum processing system 400. Each substrate is initially moved through the factory interface 420 which is coupled to the pods 430 and placed in one of the load lock chambers 412. The robotic transport mechanism within the second transfer chamber 410 transports the substrates, one at a time, from the load lock chambers 412 to the first preclean chamber 414 or second preclean chamber 416 where a cleaning process, such as the oxide cleaning described with respect to activity 102, is performed to remove oxides from a surface of a substrate. Once the oxides have been removed from the substrate surface, the robotic transport mechanism disposed within the second transfer chamber 410 transfers the substrate from the first preclean chamber 414 or second preclean chamber 416 to the pass-through station 406. Then the robotic transport mechanism disposed within the first transfer chamber 404 transfers the substrate from the pass-through station 406 to one or more processing chambers 402a-402d. The one or more processing chambers 402a-402d may include an epitaxy process chamber where a layer formation process, such as the epitaxial deposition described with respect to activity 102, is performed.

Upon completion of processing in the one or more processing chambers 402a-402d, the robotic transport mechanism disposed within the first transfer chamber 404 transfers the substrate from either one of the processing chambers 402 to the pass-through station 408. The substrate is then removed from the pass-through station 408 by the robotic transport mechanism disposed within the second transfer chamber 410 and transferred to the other load lock chamber 412 through which the substrate is withdrawn from the vacuum processing system 400. The example substrate movement sequence described above is provided for illustration purposes only, and other substrate movement sequences are contemplated.

Since the processes of all three activities 102, 104 and 106 of FIG. 1 are performed within the same vacuum processing system 400, vacuum is not broken as the substrate is transferred between chambers, which decreases the chance of contamination and improves the quality of the deposited epitaxial film. In some examples, a controller (e.g., the controller 250 shown in FIG. 2 or another similar controller) may be coupled to the vacuum processing system 400 for controlling the vacuum processing system 400 or components thereof. The controller may be used to schedule the movement of the substrates through the vacuum processing system 400 in accordance with a desired sequencing program, which may vary depending upon the application.

Benefits of the present disclosure include an improved vacuum processing system integrating a preclean process chamber and an epitaxial process chamber on the same vacuum processing system. The integrated vacuum processing system allows substrates to remain in vacuum or inert environment between oxide removal and epitaxial deposition, which reduces the time the substrates are exposed to ambient and eliminates the need to preclean the substrates on a separate processing chamber or system.

While the foregoing is directed to embodiments of the present disclosure, other and further embodiments of the disclosure may be devised without departing from the basic scope thereof.

1. A processing system, comprising:
a film formation chamber;
a transfer chamber coupled to the film formation chamber;
an oxide removal chamber coupled to the transfer chamber, the oxide removal chamber having a substrate support; and
a controller configured to:
introduce a process gas mixture into the oxide removal chamber, the process gas mixture including a fluorine-containing gas and a vapor including at least one of water, an alcohol, an organic acid, or combinations thereof; and
expose a substrate positioned on the substrate support to the process gas mixture, thereby removing an oxide film from the substrate.

2. The processing system of claim 1, wherein the alcohol comprises a primary alcohol.

3. The processing system of claim 2, wherein the alcohol comprises at least one of methyl alcohol or ethyl alcohol.

4. The processing system of claim 1, wherein the alcohol comprises a C1-C3 alcohol.

5. The processing system of claim 1, wherein the fluorine-containing gas comprises at least one of hydrogen fluoride, nitrogen fluoride, carbon fluoride, sulfur fluoride, or combinations thereof.

6. The processing system of claim 1, wherein the process gas mixture is free of ammonia.

7. The processing system of claim 1, wherein a concentration of the vapor may be about 5% wt/wt to about 75% wt/wt total process gas mixture.

8. The processing system of claim 1, wherein the substrate support comprises two or more independent temperature control zones each having a separate cooling channel.

9. The processing system of claim 1, wherein the controller is configured to maintain a temperature of the substrate support at about 0° C. or less while exposing the substrate to the process gas mixture.

10. The processing system of claim 1, wherein the controller is configured to form a film on a substrate disposed in the film formation chamber.

11. A method of processing a substrate, comprising:
removing oxide from a substrate disposed in a first process chamber by exposing the substrate to a process gas mixture including a fluorine-containing gas and a vapor including at least one of water, an alcohol, an organic acid, or combinations thereof;
transferring the substrate from the first process chamber to a second process chamber under vacuum or inert environment; and
forming a film on the substrate disposed in the second process chamber.

12. The method of claim 11, further comprising:
introducing the fluorine-containing gas to the first process chamber from a first gas source;
introducing the vapor to the first process chamber from a second gas source; and
flowing the fluorine-containing gas and the vapor through a dual-channel showerhead disposed in the first process chamber, thereby mixing the fluorine-containing gas and the vapor to form the process gas mixture before exposing the substrate to the process gas mixture.

13. The method of claim 11, wherein the process gas mixture is free of ammonia.

14. The method of claim 11, further comprising cooling the substrate to a temperature of about 0° C. or less during oxide removal.

15. The method of claim 11, wherein the oxide is removed from the substrate through reaction with the process gas mixture without the formation of solid byproducts.

16. The method of claim 11, further comprising:
providing the fluorine-containing gas and the vapor to the first process chamber separately; and
mixing the fluorine-containing gas and the vapor after arrival to the first process chamber.

17. The method of claim 11, wherein a flow ratio of the fluorine-containing gas to the vapor may be about 1:10 to about 10:1.

18. A processing system, comprising:
a film formation chamber;
a first transfer chamber coupled to the film formation chamber;
a pass-through station coupled to the first transfer chamber;
a second transfer chamber coupled to the pass-through station;
a first oxide removal chamber coupled to the second transfer chamber, wherein the first oxide removal chamber, the second transfer chamber, the pass-through station, the first transfer chamber, and the film formation chamber are maintained under vacuum or inert environment, and wherein the first oxide removal chamber comprises a first substrate support;
a computer readable medium storing instructions, that, when executed by a processor of the processing system, cause the system to:
remove oxide from a first substrate disposed in the first oxide removal chamber by exposing the first substrate to a process gas mixture including a fluorine-containing gas and a vapor including at least one of water, an alcohol, an organic acid, or combinations thereof;
transfer the first substrate to the film formation chamber; and
form a film on the first substrate disposed in the film formation chamber; and
a load lock chamber coupled to the first oxide removal chamber.

19. The processing system of claim 18, further comprising a second oxide removal chamber coupled to the second transfer chamber and maintained under vacuum or inert environment, wherein the second oxide removal chamber comprises a second substrate support, and wherein the instructions stored on the computer readable medium further cause the system to:
remove oxide from a second substrate disposed in the second oxide removal chamber by exposing the second substrate to the process gas mixture.

20. The processing system of claim 18, wherein an internal volume of the processing system is isolated from ambient environment.
